(19) United States
(12) Patent Application Publication
(10) Pub. No.: US 2026/0085258 A1
(43) Pub. Date: Mar. 26, 2026

(54) POST-CMP CLEANING COMPOSITION AND POST-CMP CLEANING METHOD

(71) Applicant: Fujimi Incorporated, Kiyosu-shi (JP)

(72) Inventor: Haruka ASANO, Kiyosu-shi (JP)

(73) Assignee: Fujimi Incorporated, Kiyosu-shi (JP)

(21) Appl. No.: 19/331,678

(22) Filed: Sep. 17, 2025

(30) Foreign Application Priority Data
Sep. 20, 2024 (JP) 2024-163570

(51) Int. Cl. C11D 3/12; C11D 1/00; C11D 3/00

(52) U.S. Cl. CPC C11D 3/12; C11D 1/008; C11D 3/0047; C11D 2111/22

(57) ABSTRACT

There are provided a post-CMP cleaning composition and a post-CMP cleaning method, which can more efficiently reduce cerium remaining on a surface of polished objects to be polished.

The post-CMP cleaning composition is used for cleaning polished objects to be polished as objects to be polished, which has been subjected to a chemical mechanical polishing (CMP) using a polishing composition containing a cerium compound as abrasives, the post-CMP cleaning composition containing silica and a water-soluble polymer. A concentration of the silica is 0.5% by mass or more and 10% by mass or less.

### TECHNICAL FIELD

The present invention relates to a post-CMP cleaning composition and a post-CMP cleaning method.

### BACKGROUND ART

In recent years, along with multilayer wiring on a surface of a semiconductor substrate, a so-called chemical mechanical polishing (CMP) art has been utilized to polish and flatten the semiconductor substrate when manufacturing a device. The CMP is a method of flattening a surface of objects to be polished (polishing target) such as the semiconductor substrate, using a polishing composition (slurry) containing abrasives such as silica, alumina, and ceria, an anticorrosive agent, a surfactant, and the like, in which the objects to be polished (polishing target) is for example, silicon, polysilicon, a silicon oxide film (silicon oxide), a silicon nitride, a wiring and a plug consisting a metal, or the like.

In a case of polishing a silicon dioxide film (hereinafter, referred to as a TEOS film) formed of tetraethoxysilane (Si(OC₂H₅)₄) among objects to be polished, a cerium compound such as ceria (CeO₂) is used as abrasives. This is because, when the cerium (Ce) in the cerium compound forms a bond with the silicon oxide in the TEOS film, the silicon-oxygen bond in the silicon oxide is weakened, and thus the polishing is facilitated.

On the other hand, it has been known that, when the TEOS film is polished with a polishing composition containing a cerium compound as abrasives, cerium is likely to remain on a surface of the semiconductor substrate after the polishing. Impurities such as cerium remaining on the surface of the semiconductor substrate may adversely affect electrical characteristics of the semiconductor, and may deteriorate reliability of the device. Therefore, it is desirable to introduce a cleaning step after the CMP step to remove the impurities from the surface of the semiconductor substrate.

### CITATION LIST

### Patent Literature

PTL 1: WO 2018/168207A1

### SUMMARY

### Technical Problem

However, since the residual cerium as described above is bonded to the silicon oxide in the TEOS film, it is difficult to remove residues containing the cerium by a normal cleaning step. Therefore, in PTL 1, in order to reduce the residues containing cerium after the CMP step, a surface treatment composition containing a carboxy group-containing (co) polymer, an SO_{X} or NO_{Y} partial structure compound, and a dispersion medium, and having a pH of 1 or more and 8 or less is proposed.

In addition, in recent years, miniaturization of the surface of the semiconductor substrate has progressed, and the influence of the impurities remaining on the semiconductor substrate has become more significant. Therefore, there is a demand for a cleaning composition and a cleaning method, which can further reduce the cerium remaining on the surface of the semiconductor substrate after the CMP polishing.

The present invention has been made in view of such circumstances, and an object of the present invention is to provide a post-CMP cleaning composition and a post-CMP cleaning method, which can more efficiently reduce cerium remaining on a surface of polished objects to be polished.

### Solution to Problem

A post-CMP cleaning composition according to one aspect of the present invention is used for cleaning polished objects to be polished as objects to be polished, which has been subjected to a chemical mechanical polishing (CMP) using a polishing composition containing a cerium compound as abrasives, the post-CMP cleaning composition containing silica and a water-soluble polymer, in which a concentration of the silica is 0.5% by mass or more and 10% by mass or less.

In addition, a post-CMP cleaning method according to another aspect of the present invention includes post-CMP cleaning of polished objects to be polished which has been subjected to CMP using a polishing composition containing a cerium compound as abrasives, using the post-CMP cleaning composition according to the aspect of the present invention.

### Advantageous Effects

According to the present invention, it is possible to provide a post-CMP cleaning composition and a post-CMP cleaning method, which can more efficiently reduce cerium remaining on a surface of polished objects to be polished.

### DESCRIPTION OF EMBODIMENTS

Embodiments of the present invention will be described in detail. The following embodiments show examples of the present invention, but the present invention is not limited to the embodiments. In addition, various changes or enhancements can be added to the following embodiments, and the present invention may also include embodiments to which such changes or enhancements have been added.

### (Post-CMP Cleaning Composition)

One embodiment according to the present invention is a post-CMP cleaning composition used for cleaning polished objects to be polished as objects to be polished, which has been subjected to a chemical mechanical polishing (CMP) using a polishing composition containing a cerium compound as abrasives, the post-CMP cleaning composition containing silica and a water-soluble polymer. In addition, a concentration of the silica is 0.5% by mass or more and 10% by mass or less.

The present inventors have found that cerium remaining on a surface of the polished objects to be polished can be more efficiently removed by using the post-CMP cleaning composition having the above-described configuration.

### (Polished Objects to be Polished)

The polished objects to be polished means objects to be polished, which has been polished in a polishing step. The polishing step is a chemical mechanical polishing (CMP) step, and the polishing composition used in the CMP step contains a cerium compound as abrasives.

The polished objects to be polished according to the present invention is preferably a polished semiconductor substrate. Here, when residues are present on a surface of the polished semiconductor substrate, performance of the semiconductor device is degraded. Therefore, when the polished objects to be polished is a semiconductor substrate, it is necessary to remove the residues as much as possible in the post-CMP cleaning of the semiconductor substrate. Since the post-CMP cleaning composition according to the embodiment of the present invention has an effect of efficiently removing residues containing cerium, the post-CMP cleaning composition can be suitably used for post-CMP cleaning of such a polished semiconductor substrate.

The post-CMP cleaning composition according to the embodiment of the present invention can more efficiently remove cerium remaining on a surface of the polished objects to be polished. When the TEOS film is polished using a polishing composition containing cerium, the cerium is likely to remain on the surface of the polished objects to be polished. Therefore, it is preferable to apply the polishing composition to the polished objects to be polished including the TEOS film. In addition, the polished objects to be polished may further include a simple substance of silicon, a silicon compound, carbon, a metal, or the like. These components may be used alone or in combination of two or more types thereof.

Examples of the simple substance of silicon include single crystal silicon, polycrystalline silicon (polysilicon), and amorphous silicon. Examples of the silicon compound include silicon nitride (SiN), silicon oxide (SiO₂), and silicon carbide (SiC). The silicon oxide film includes a silicon oxide film derived from a material other than TEOS. The silicon compound film includes a low permittivity film having a relative permittivity of 3 or less. Furthermore, examples of the metal include tungsten, copper, aluminum, hafnium, cobalt, nickel, titanium, tantalum, gold, silver, platinum, palladium, rhodium, ruthenium, iridium, and osmium. These metals may be contained in the form of an alloy or a metal compound.

### (Residue)

In the present specification, the residue means a contaminant attached to the surface of the polished objects to be polished. Examples of the residue include a particle residue, an organic residue, and other residues.

The particle residue means a component derived from a granular inorganic substance such as abrasives, which is contained in the polishing composition among contaminants attached to the surface of the polished objects to be polished. The organic residue means a component consisting of an organic substance such as an organic low-molecular-weight compound and an organic high-molecular-weight compound, or an organic salt, among contaminants attached to the surface of the polished objects to be polished. In addition, the other residues mean residues consisting of a component other than the particle residue and the organic residue, a mixture of the particle residue and the organic residue, and the like. Usually, the cerium remaining on the surface of the semiconductor substrate subjected to the CMP treatment using the polishing composition containing a cerium compound as abrasives is present as the particle residue.

The color and the shape of the particle residue, the organic residue, and the other residues are significantly different from each other. Therefore, the determination of whether or not the contaminants are the particle residue can be performed by visual observation with a scanning electron microscope (SEM) or the like, element analysis with an energy dispersive X-ray analysis (EDX) device attached to the scanning electron microscope, or the like. In addition, the measurement of the amount of particle residue can also be performed using a wafer defect inspection device, a scanning electron microscope, energy dispersive X-ray analysis, or an inductively coupled plasma mass spectrometry (ICP-MS) device.

### (Abrasives)

The post-CMP cleaning composition according to the embodiment of the present invention contains the silica as abrasives. In the present specification, the silica has an action of mechanically polishing and removing the residues containing cerium, which are attached to the surface of the polished objects to be polished. As the silica, a commercially available product may be used, or a synthetic product may be used.

The type of the silica is not particularly limited. Examples of the type of the silica include colloidal silica and fumed silica, and colloidal silica is preferable.

Examples of a method for producing the colloidal silica include a sodium silicate method and a sol-gel method. The colloidal silica may be colloidal silica produced by any production method, but from the viewpoint of reducing metal impurities, colloidal silica produced by a sol-gel method is preferable. The colloidal silica produced by the sol-gel method is preferable because it has a small content of corrosive ions such as metal impurities and chloride ions, which have a property of diffusing in a semiconductor. The production of the colloidal silica by the sol-gel method can be performed by a conventionally known method. Specifically, the colloidal silica can be obtained by carrying out a hydrolysis-condensation reaction using a hydrolyzable silicon compound (for example, alkoxysilane or derivatives thereof) as a raw material.

The silica may be colloidal silica in which an organic acid is fixed to a surface. As the colloidal silica in which an organic acid is fixed to a surface, colloidal silica in which an organic acid group such as a carboxyl group, a sulfo group, a phosphonic acid group, and an aluminate group is fixed to the surface may be used; but among these, colloidal silica in which a sulfo group is fixed to the surface is suitable. That is, the colloidal silica is preferably sulfonic acid-modified colloidal silica.

A method for producing the colloidal silica in which an organic acid is fixed to a surface is not particularly limited, and examples thereof include a method of reacting a silane coupling agent having an organic acid group at a terminal with colloidal silica.

As a specific example, when the sulfo group is fixed on the colloidal silica, the production can be carried out, for example, by the method described in “Sulfonic acid-functionalized silica through of thiol groups”, Chem. Commun. 246-247 (2003). Specifically, the colloidal silica in which the sulfo group is fixed on the surface (sulfonic acid-modified colloidal silica) can be obtained by coupling a silane coupling agent having a thiol group, such as 3-mercaptopropyltrimethoxysilane, to the colloidal silica and then oxidizing the thiol group with hydrogen peroxide.

When the carboxyl group is fixed on the colloidal silica, for example, the fixing can be performed by a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, the colloidal silica in which the carboxyl group is fixed on the surface (carboxylic acid-modified colloidal silica) can be obtained by coupling a silane coupling agent having a photoreactive 2-nitrobenzyl ester to colloidal silica, and then performing light irradiation.

### Shape of Silica)

The shape of the silica is not particularly limited. For example, the shape of the silica may be spherical or non-spherical. Specific examples of the non-spherical shape include various shapes such as a polygonal prism shape such as a triangular prism or a tetragonal prism, a cylindrical shape, a straw bag shape in which a central part of a cylinder is inflated compared to end parts, a doughnut shape in which a central part of a cylinder is perforated through, a plate shape, a so-called cocoon-like shape having a constriction in the middle part, a so-called associated type spherical shape in which a plurality of particles are integrated, a so-called konpeito shape having a plurality of bumps on the surface, and a rugby ball shape; but there are no particular limitations.

### (Zeta Potential of Silica)

A zeta potential of the silica in the post-CMP cleaning composition according to the present embodiment is not particularly limited. For example, the silica may have a negative zeta potential. When the zeta potential of the silica is negative, aggregation of the silica is suppressed, so that the residues containing cerium can be efficiently removed. In addition, since a polishing removal rate for the TEOS film can be suppressed to be low, it is easy to adjust the polishing time. The upper limit of the zeta potential of the silica may be, for example, −10 mV or less, −20 mV or less, or −30 mV or less. In addition, the lower limit of the zeta potential of the silica may be, for example, −70 mV or more, −60 mV or more, or −50 mV or more.

### (Average Primary Particle Diameter of Silica)

The size of the silica is not particularly limited. An average primary particle diameter of the silica may be, for example, 5 nm or more, 8 nm or more, or 10 nm or more. When the average primary particle diameter of the silica is 5 nm or more, the residues attached to the surface of the polished objects to be polished are easily removed by the post-CMP cleaning composition. In addition, the average primary particle diameter of the silica may be 200 nm or less, 150 nm or less, or 100 nm or less. When the average primary particle diameter of the silica is 200 nm or less, a surface with fewer defects is easily obtained by polishing with the post-CMP cleaning composition. The average primary particle diameter of the silica can be calculated, for example, on the assumption that the shape of the silica is a perfect sphere, based on the specific surface area (SA) of the silica calculated by the BET method. For example, the average primary particle diameter of the silica can be calculated from the specific surface area of the silica measured by the BET method and the true density of the silica, using “Flow Sorb II 2300” manufactured by Micromeritics Instrument Corporation.

### (Average Secondary Particle Diameter of Silica)

An average secondary particle diameter of the silica is not particularly limited. The average secondary particle diameter of the silica may be, for example, 10 nm or more, 30 nm or more, or 50 nm or more. As the average secondary particle diameter of the silica increases, resistance during polishing decreases, and thus stable polishing is possible. In addition, the average secondary particle diameter of the silica may be 300 nm or less, 200 nm or less, or 100 nm or less. As the average secondary particle diameter of the silica decreases, the specific surface area of the silica per unit mass increases. Therefore, the frequency of contact with the residues containing cerium is improved, and thus the removal rate of the residues containing cerium is further improved. The average secondary particle diameter of the silica can be measured by, for example, a dynamic light scattering method typified by a laser diffraction scattering method.

### (Concentration of Silica)

In addition, the concentration of the silica in the post-CMP cleaning composition according to the present embodiment is 0.5% by mass or more and 10% by mass or less. When the concentration of the silica is 0.5% by mass or more, the residues containing cerium can be sufficiently removed. When the concentration of the silica is 10% by mass or less, it is possible to suppress not only the cost of the post-CMP cleaning composition but also excessive polishing of the polished objects to be polished on the semiconductor substrate in the post-CMP cleaning. In addition, the lower limit of the concentration of the silica may be 1% by mass or more, 1.5% by mass or more, or 2% by mass or more. The upper limit of the concentration of the silica may be 8% by mass or less, 7% by mass or less, or 6% by mass or less. That is, the concentration of the silica in the post-CMP cleaning composition may be 18 by mass or more and 8% by mass or less, 1.5% by mass or more and 7% by mass or less, or 2% by mass or more and 6% by mass or less.

### (Water-Soluble Polymer)

The post-CMP cleaning composition according to the present embodiment contains a water-soluble polymer. The type of the water-soluble polymer is not particularly limited. Examples of the type of the water-soluble polymer include an anionic water-soluble polymer and a nonionic water-soluble polymer. The water-soluble polymer may be used alone or in combination of two or more types thereof. That is, the water-soluble polymer may be at least one of the anionic water-soluble polymer or the nonionic water-soluble polymer.

The type of the nonionic water-soluble polymer is not particularly limited, but it is preferable that the nonionic water-soluble polymer has a structural unit derived from a monomer having a vinyl group. Examples of the monomer having a vinyl group include vinyl alcohol, vinyl acetate, N-vinyl-2-pyrrolidone, N-vinylcaprolactam, N-vinylvalerolactam, N-vinyllaurolactam, N-vinylpiperidone, and acrylamide. The nonionic water-soluble polymer can be produced, for example, by polymerizing the above-described monomers by a reaction between vinyl groups of the monomers. That is, the nonionic water-soluble polymer may be a polymer using the monomer having a vinyl group as a raw material. The monomer having a vinyl group may be used alone or in combination of two or more types thereof. When the post-CMP cleaning composition contains such a nonionic water-soluble polymer, the residues removed by the post-CMP cleaning are less likely to be reattached to the surface of the polished objects to be polished. Examples of the nonionic water-soluble polymer include polyvinyl alcohol (PVA), polyvinylpyrrolidone (PVP), polyvinylcaprolactam, polyvinylvalerolactam, polyvinyllaurolactam, polyvinylpiperidone, polyacrylamide, poly-N-vinylacetamide, and a butanediol-vinyl alcohol copolymer. These nonionic water-soluble polymers may be used alone or in combination of two or more types thereof.

The type of the anionic water-soluble polymer is not particularly limited, but it is preferable that the anionic water-soluble polymer has a sulfo group. When the anionic water-soluble polymer having a sulfo group is used as the water-soluble polymer, the zeta potential of the silica is likely to be negative. As a result, since the silica is less likely to aggregate, the residues on the surface of the polished objects to be polished are easily removed. Examples of the anionic water-soluble polymer having a sulfo group include polyvinylsulfonic acid, polystyrenesulfonic acid, polyallylsulfonic acid, polymethallylsulfonic acid, poly(2-acrylamido-2-methylpropane sulfonic acid), polyisoprenesulfonic acid, a (meth)acrylic acid-isoprenesulfonic acid copolymer, a (meth)acrylic acid-[2-(meth)acrylamido-2-methylpropane sulfonic acid] copolymer, and a (meth)acrylic acid-isoprenesulfonic acid-[2-(meth)acrylamido-2-methylpropane sulfonic acid] copolymer. These anionic water-soluble polymers may have a form of a neutralized salt. These anionic water-soluble polymers may be used alone or in combination of two or more types thereof.

A concentration of the water-soluble polymer in the post-CMP cleaning composition according to the present embodiment is not particularly limited. Here, the concentration of the water-soluble polymer means a ratio of the total of the content of the nonionic water-soluble polymer and the content of the anionic water-soluble polymer to the total amount of the post-CMP cleaning composition ((Content of anionic water-soluble polymer+Content of nonionic water-soluble polymer)/Total amount of post-CMP cleaning composition).

The lower limit value of the concentration of the water-soluble polymer in the post-CMP cleaning composition may be 0.01% by mass or more, 0.02% by mass or more, or 0.03% by mass or more. When the concentration of the water-soluble polymer is 0.01% by mass or more, the residues on the surface of the polished objects to be polished can be more efficiently removed. In addition, the upper limit of the concentration of the water-soluble polymer in the post-CMP cleaning composition may be 1% by mass or less, 0.5% by mass or less, 0.1% by mass or less, or 0.08% by mass or less. When the concentration of the water-soluble polymer is 1% by mass or less, it is possible to suppress not only the cost of the post-CMP cleaning composition but also deterioration of dispersion stability of the abrasives.

A weight-average molecular weight (Mw) of the water-soluble polymer in the post-CMP cleaning composition according to the present embodiment is not particularly limited. A lower limit value of a weight-average molecular weight of the water-soluble polymer may be, for example, 1,000 or more, 1,500 or more, or 2,000 or more. In addition, an upper limit value of the weight-average molecular weight of the water-soluble polymer may be, for example, 1,500,000 or less, 1,300,000 or less, or 1,000,000 or less. The weight-average molecular weight of the water-soluble polymer can be measured as a value in terms of polyethylene glycol using gel permeation chromatography (GPC).

### (Liquid Medium)

The post-CMP cleaning composition according to the present embodiment may contain a liquid medium. The liquid medium functions as a dispersion medium or a solvent for dispersing or dissolving each component of the post-CMP cleaning composition (the silica, the water-soluble polymer, and, as necessary, an additive such as a pH adjuster). Examples of the liquid medium include water and an organic solvent, and only one type thereof may be used alone, or two or more types thereof may be used in combination. Among these, water is preferably contained. However, from the viewpoint of preventing the effect of each component from being inhibited, it is preferable to use water which contains as little impurities as possible. Specifically, pure water or ultrapure water, from which impurity ions have been removed with an ion exchange resin and contaminants have been removed through a filter, or distilled water is preferable.

### (pH of Post-CMP Cleaning Composition)

A pH of the post-CMP cleaning composition according to the present embodiment may be 7 or less, or may be less than 5. When the pH of the post-CMP cleaning composition is 7 or less, the zeta potential of the silica is likely to be negative. As a result, since the aggregation of the silica is suppressed, the residues containing cerium can be efficiently removed. In addition, the pH of the post-CMP cleaning composition according to the present embodiment may be 1 or more, 2 or more, or 3 or more. When the pH of the post-CMP cleaning composition is 1 or more, not only is it difficult for consumable parts such as a polishing pad in contact with the post-CMP cleaning composition and a polishing device to deteriorate, but also it is possible to suppress the generation of new residues associated with the deterioration of the device and the part. The pH of the post-CMP cleaning composition can be measured by the method described in Examples.

The post-CMP cleaning composition according to the present embodiment may further contain a pH adjuster in order to adjust the pH to the above-described range. As the pH adjuster, an acid, a base, or both of the acid and the base may be used; or an inorganic compound, an organic compound, or both of the inorganic compound and the organic compound may be used.

Examples of the acid as the pH adjuster include an inorganic acid and an organic acid. Examples of the inorganic acid include sulfuric acid, nitric acid, boric acid, carbonic acid, hypophosphorous acid, phosphorous acid, and phosphoric acid. Examples of the organic acid include a carboxylic acid and an organic sulfuric acid. Specific examples of the carboxylic acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid. Furthermore, examples of the organic sulfuric acid include methanesulfonic acid, ethanesulfonic acid, and isethionic acid. These acids may be used alone or in combination of two or more types thereof.

Examples of the base as the pH adjuster include an alkali metal hydroxide or a salt thereof, an alkaline earth metal hydroxide or a salt thereof, a quaternary ammonium hydroxide or a salt thereof, ammonia, and amine. Examples of the alkali metal include potassium and sodium. In addition, examples of the alkaline earth metal include calcium and strontium. Furthermore, examples of the salt include a carbonate, a hydrogen carbonate, a sulfate, and an acetate. Furthermore, examples of the quaternary ammonium include tetramethylammonium, tetraethylammonium, and tetrabutylammonium.

Examples of the quaternary ammonium hydroxide compound include a quaternary ammonium hydroxide or a salt thereof; and specific examples thereof include tetramethylammonium hydroxide, tetraethylammonium hydroxide, and tetrabutylammonium hydroxide. Furthermore, examples of the amine include methylamine, dimethylamine, trimethylamine, ethylamine, diethylamine, triethylamine, ethylenediamine, monoethanolamine, N-(β-aminoethyl) ethanolamine, hexamethylenediamine, diethylenetriamine, triethylenetetramine, piperazine anhydrous, piperazine hexahydrate, 1-(2-aminoethyl) piperazine, N-methylpiperazine, and guanidine. These bases may be used alone or in combination of two or more types thereof.

Furthermore, as the pH adjuster, a buffered pH adjuster which is a mixture of the acid and the salt of the acid may be used. It is preferable to use a buffered pH adjuster because the pH variation during the post-CMP cleaning can be reduced. Examples of the combination of the mixture of the acid and the salt of the acid include a combination of an acid such as citric acid, acetic acid, and lactic acid, and a salt such as an ammonium salt, a sodium salt, and a potassium salt of the acid. From the viewpoint of impurities, an ammonium salt is preferably used as the salt. In addition, as the combination of the acid and the salt of the acid, a combination of citric acid and triammonium citrate is particularly preferable because it not only reduces the fluctuation of pH but also has a chelating effect on cerium.

### (Other Additives)

The post-CMP cleaning composition according to the embodiment of the present invention may further contain a known additive such as a surfactant, a chelating agent, an oxidant, a thickener, a dispersing agent, a surface protector, an anti-cavity agent, and a preservative, as long as the effect of the present invention is not impaired. A content of the above-described additive may be appropriately set according to the purpose of addition.

### <Method for Producing Post-CMP Cleaning Composition>

A method for producing the post-CMP cleaning composition according to one aspect of the present invention is not particularly limited. The post-CMP cleaning composition can be obtained, for example, by stirring and mixing the silica, the water-soluble polymer, and other additives as necessary in the liquid medium. A temperature at the time of mixing the respective components is not particularly limited, but is preferably 10° C. or higher and 40° C. or lower; and the mixture may be heated in order to increase a dissolution rate. In addition, a mixing time is not particularly limited as long as the components can be uniformly mixed.

### <Post-CMP Cleaning Method>

The post-CMP cleaning method according to another aspect of the present invention is a method for cleaning polished objects to be polished as objects to be polished, which has been subjected to a CMP using a polishing composition containing a cerium compound as abrasives, the method including cleaning the polished objects to be polished using the above-described post-CMP cleaning composition.

In the present specification, the post-CMP cleaning is a method of reducing residues on the surface of the polished objects to be polished after the CMP, that is, in the post-CMP, and is a method of performing a cleaning in a broad sense. According to the post-CMP cleaning method according to the present aspect, the residues containing cerium, remaining on the surface of the polished objects to be polished, can be effectively removed.

The post-CMP cleaning method according to the present aspect is performed by a method of bringing the post-CMP cleaning composition into direct contact with the surface of the polished objects to be polished. The post-CMP cleaning is not particularly limited, but can be performed by, for example, a rinse polishing treatment. The rinse polishing treatment is performed to remove contaminants, particularly particle residues containing cerium, present on the surface of the polished objects to be polished, and to obtain a clean surface.

The rinse polishing treatment is performed on a polishing platen (platen) on which a polishing pad is attached after final polishing (finish polishing) for the purpose of removing contaminants on the surface of the objects to be polished. At this time, the residues on the surface of the polished objects to be polished are removed by a frictional force (physical action) of the polishing pad and the action of the post-CMP cleaning composition. Among the residues, the particle residue is easily removed by the physical action. Therefore, the particle residue can be efficiently removed by the rinse polishing treatment.

As a polishing device, a general polishing device having a holder which holds the objects to be polished, a motor of which the rotation speed is changeable, and a polishing platen on which a polishing pad can be attached can be used. In addition, as the polishing device, any one of a single-sided polishing device or a double-sided polishing device may be used. When both the CMP treatment and the rinse polishing treatment are performed using the same polishing device, it is preferable that the polishing device includes a discharge nozzle for the post-CMP cleaning composition according to one aspect of the present invention, in addition to a discharge nozzle for a polishing composition.

As the polishing pad, general nonwoven fabric, polyurethane, porous fluororesin, and the like can be used without particular limitation. It is preferable that the polishing pad is subjected to groove processing such that a polishing liquid is accumulated.

Rinse polishing conditions are not particularly limited, and can be appropriately set according to the characteristics of the post-CMP cleaning composition and the polished objects to be polished.

A pressure (polishing pressure) applied to the polished objects to be polished during the rinse polishing may be 0.5 psi (3.4 kPa) or more and 10 psi (68.9 kPa) or less.

A polishing time during the rinse polishing is not particularly limited. In general, the lower limit of the polishing time during the rinse polishing may be 5 seconds or more, 10 seconds or more, 15 seconds or more, or 20 seconds or more. In addition, from the viewpoint of efficiently removing the residues, the upper limit of the polishing time during the rinse polishing may be 180 seconds or less, 150 seconds or less, 120 seconds or less, or 100 seconds or less.

A rotation speed of the polishing platen during the rinse polishing is not particularly limited. In general, the lower limit of the rotation speed of the polishing platen during the rinse polishing may be 10 rpm (0.17 s⁻¹) or more, 20 rpm (0.33 s⁻¹) or more, or 30 rpm (0.5 s⁻¹) or more. In addition, the upper limit of the rotation speed of the polishing platen during the rinse polishing may be 500 rpm (8.3 s⁻¹) or less, 300 rpm (5 s⁻¹) or less, or 200 rpm (3.3 s⁻¹) or less.

A method of supplying the post-CMP cleaning composition in the rinse polishing is not particularly limited, and a method of continuously supplying (the one-way) the post-CMP cleaning composition with a pump or the like may be adopted. A supply amount of the post-CMP cleaning composition (a flow rate of the post-CMP cleaning composition) is not particularly limited as long as the entire polished objects to be polished is covered, but is generally 100 mL/min or more and 5,000 mL/min or less.

The cleaning with water may be carried out before or after the step of performing the post-CMP cleaning method according to one aspect of the present invention, or both before and after the step. Thereafter, water droplets attached to the surface of the polished objects to be polished may be removed and dried by a spin dryer, air blowing, or the like.

### EXAMPLES

The present invention will be described in more detail with reference to Examples and Comparative Examples. However, the scope of the art of the present invention is not limited to the following examples. In addition, various changes or enhancements can be added to the following examples, and the present invention may also include embodiments to which such changes or enhancements have been added.

### Preparation of CMP Cleaning Composition

### Example 1

A post-CMP cleaning composition of Example 1 was prepared by stirring and mixing sulfonic acid-modified colloidal silica particles (average secondary particle diameter: 70 nm) as abrasives, polyvinyl alcohol (weight-average molecular weight: 10,000) as a nonionic water-soluble polymer, sodium polystyrene sulfonate (weight-average molecular weight: 200,000) as an anionic water-soluble polymer, citric acid and triammonium citrate as a pH adjuster, and water as a liquid medium. Each component was added so that the concentration of the sulfonic acid-modified colloidal silica was 0.50% by mass, the concentration of the polyvinyl alcohol was 0.01% by mass, and the concentration of the sodium polystyrene sulfonate was 0.032% by mass, with respect to the total amount of the post-CMP cleaning composition of Example 1. In addition, the citric acid and ammonium triammide citrate were added so that the pH of the post-CMP cleaning composition was 3.4. A pH of the post-CMP cleaning composition was confirmed with a pH meter (product name: LAQUA (registered trademark) manufactured by Horiba, Ltd.).

### Examples 2 to 5

Post-CMP cleaning compositions of Examples 2 to 5 were prepared in the same manner as in Example 1, except that the concentration of the sulfonic acid-modified colloidal silica was changed as shown in Table 1.

### Example 6

A post-CMP cleaning composition of Example 6 was prepared in the same manner as in Example 1, except that the polyvinyl alcohol was not added.

### Example 7

A post-CMP cleaning composition of Example 7 was prepared in the same manner as in Example 1, except that the sodium polystyrene sulfonate was not added.

### Examples 8 to 10

Post-CMP cleaning compositions of Examples 8 to 10 were prepared in the same manner as in Example 1, except that the pH was changed as shown in Table 1.

### Example 11

A post-CMP cleaning composition of Example 11 was prepared in the same manner as in Example 1, except that silica modified with a cation by (3-aminopropyl)triethoxysilane (APTES) (average secondary particle diameter: 70 nm) was used as the abrasives and the anionic water-soluble polymer was not added.

### Comparative Example 1

A post-CMP cleaning composition of Comparative Example 1 was prepared in the same manner as in Example 1, except that the sulfonic acid-modified colloidal silica was not added.

### Comparative Example 2

A post-CMP cleaning composition of Comparative Example 2 was prepared in the same manner as in Example 1, except that the polyvinyl alcohol and the sodium polystyrene sulfonate were not added.

### <Measurement of Zeta Potential>

For the post-CMP cleaning compositions of Examples 1 to 11 and Comparative Examples 1 and 2, a zeta potential of abrasives was measured using a zeta potential/particle size measurement system ELS-Z2 manufactured by OTSUKA ELECTRONICS Co., Ltd. Specifically, the post-CMP cleaning composition was subjected to the zeta potential/particle size measurement system, and the zeta potential was calculated by performing measurement using a flow cell by a laser Doppler method (electrophoretic light scattering measurement method) at a measurement temperature of 25° C. and analyzing the obtained data according to the formula of Smoluchowski. The results are shown in Table 1.

TABLE 1

| | Abrasive | | | | | | |
|---|---|---|---|---|---|---|---|
| | | | Average | | | | |
| | | | secondary | Nonionic water- | | Anionic water-soluble | |
| | | | particle | soluble polymer | | polymer | |
| | | Concentration | diameter | | Concentration | | Concentration |
| No. | Type | [% by mass] | [nm] | Type | [% by mass] | Type | [% by mass] |
| Ex. 1 | Sulfonic acid- | 0.5 | 70 | Polyvinyl | 0.01 | Sodium | 0.032 |
| | modified | | | alcohol | | polystyrene | |
| | colloidal silica | | | | | sulfonate | |
| Ex. 2 | Sulfonic acid- | 2.5 | 70 | Polyvinyl | 0.01 | Sodium | 0.032 |
| | modified | | | alcohol | | polystyrene | |
| | colloidal silica | | | | | sulfonate | |
| Ex. 3 | Sulfonic acid- | 5.0 | 70 | Polyvinyl | 0.01 | Sodium | 0.032 |
| | modified | | | alcohol | | polystyrene | |
| | colloidal silica | | | | | sulfonate | |
| Ex. 4 | Sulfonic acid- | 1.0 | 70 | Polyvinyl | 0.01 | Sodium | 0.032 |
| | modified | | | alcohol | | polystyrene | |
| | colloidal silica | | | | | sulfonate | |
| Ex. 5 | Sulfonic acid- | 10.0 | 70 | Polyvinyl | 0.01 | Sodium | 0.032 |
| | modified | | | alcohol | | polystyrene | |
| | colloidal silica | | | | | sulfonate | |
| Ex. 6 | Sulfonic acid- | 5.0 | 70 | None | — | Sodium | 0.032 |
| | modified | | | | | polystyrene | |
| | colloidal silica | | | | | sulfonate | |
| Ex. 7 | Sulfonic acid- | 5.0 | 70 | Polyvinyl | 0.01 | None | — |
| | modified | | | alcohol | | | |
| | colloidal silica | | | | | | |
| Ex. 8 | Sulfonic acid- | 5.0 | 70 | Polyvinyl | 0.01 | Sodium | 0.032 |
| | modified | | | alcohol | | polystyrene | |
| | colloidal silica | | | | | sulfonate | |
| Ex. 9 | Sulfonic acid- | 5.0 | 70 | Polyvinyl | 0.01 | Sodium | 0.032 |
| | modified | | | alcohol | | polystyrene | |
| | colloidal silica | | | | | sulfonate | |
| Ex. 10 | Sulfonic acid- | 5.0 | 70 | Polyvinyl | 0.01 | Sodium | 0.032 |
| | modified | | | alcohol | | polystyrene | |
| | colloidal silica | | | | | sulfonate | |
| Ex. 11 | Cation-modified | 5.0 | 70 | Polyvinyl | 0.01 | None | — |
| | colloidal silica | | | alcohol | | | |
| Comp. | None | — | — | Polyvinyl | 0.01 | Sodium | 0.032 |
| Ex. 1 | | | | alcohol | | polystyrene | |
| | | | | | | sulfonate | |
| Comp. | Sulfonic acid- | 5.0 | 70 | None | — | None | — |
| Ex. 2 | modified | | | | | | |
| | colloidal silica | | | | | | |

| | | | | | | | Amount of cerium |
|---|---|---|---|---|---|---|---|
| | | | Zeta | Rinse polishing amount | | | residue on TEOS |
| | pH adjuster | | potential | TEOS | SiN | poly-Si | film |
| No. | Type | pH | [V] | [Å] | [Å] | [Å] | [10¹⁰ atoms/cm²] |
| Ex. 1 | Citric acid and ammonium | 3.4 | −38.7 | 7 | 5 | 59 | 9.80 |
| | triammide citrate | | | | | | |
| Ex. 2 | Citric acid and ammonium | 3.4 | −38.1 | 26 | 5 | 56 | 2.70 |
| | triammide citrate | | | | | | |
| Ex. 3 | Citric acid and ammonium | 3.4 | −37.3 | 64 | 7 | 50 | 0.58 |
| | triammide citrate | | | | | | |
| Ex. 4 | Citric acid and ammonium | 3.4 | −38.5 | 11 | 5 | 58 | 6.81 |
| | triammide citrate | | | | | | |
| Ex. 5 | Citric acid and ammonium | 3.4 | −35.8 | 125 | 10 | 41 | 0.03 |
| | triammide citrate | | | | | | |
| Ex. 6 | Citric acid and ammonium | 3.4 | −39.5 | 70 | 8 | 5 | 3.50 |
| | triammide citrate | | | | | | |
| Ex. 7 | Citric acid and ammonium | 3.4 | −38.3 | 138 | 230 | 46 | 2.66 |
| | triammide citrate | | | | | | |
| Ex. 8 | Citric acid and ammonium | 2.0 | −36.6 | 85 | 8 | 56 | 0.50 |
| | triammide citrate | | | | | | |
| Ex. 9 | Citric acid and ammonium | 5.0 | −40.9 | 56 | 3 | 43 | 1.30 |
| | triammide citrate | | | | | | |
| Ex. 10 | Citric acid and ammonium | 7.0 | −44.4 | 43 | 5 | 35 | 2.30 |
| | triammide citrate | | | | | | |
| Ex. 11 | Citric acid and ammonium | 3.4 | 27.5 | 380 | 5 | 46 | 1.30 |
| | triammide citrate | | | | | | |
| Comp. | Citric acid and ammonium | 3.4 | — | 8 | 4 | 46 | 12.00 |
| Ex. 1 | triammide citrate | | | | | | |
| Comp. | Citric acid and ammonium | 3.4 | −53.5 | 59 | 260 | 7 | 11.60 |
| Ex. 2 | triammide citrate | | | | | | |

### <Preparation of Polished Objects to be Polished>

Polished objects to be polished that had been polished with a polishing composition containing a cerium compound as abrasives was prepared by a CMP treatment described below.

### (Cmp Treatment)

As the objects to be polished, a silicon wafer with a silicon dioxide film (TEOS film), a silicon wafer with a silicon nitride film (SiN film), and a silicon wafer with a polysilicon film (Poly-Si film) were prepared. The silicon dioxide film is a film formed by a physical vapor deposition method (PVD), and the silicon nitride film and the polysilicon film are films formed by a low pressure chemical vapor deposition method (LPCVD). In addition, a thickness of each film was set to 10,000 Å for the silicon dioxide film, 2,500 Å for the silicon nitride film, and 5,000 Å for the polysilicon film.

Each of the above-described silicon wafers was polished using a polishing composition containing cerium oxide as abrasives (formulation; cerium oxide (average secondary particle diameter of 200 nm) as abrasives: 1% by mass, acetic acid as a pH adjuster: 18 by mass, solvent:water), and the polishing was performed under the following conditions with the following device, thereby obtaining the polished objects to be polished. Thereafter, the obtained polished objects to be polished was removed from the polishing platen.

### <CMP Treatment Device and Conditions>

Polishing device: FREX300E, a single-sided polishing device for 300 mm CMP manufactured by Ebara Corporation
Polishing pad: rigid polyurethane pad IC1010 manufactured by Nitta Haas Inc.
Polishing pressure: 3.0 psi (1 psi=6894.76 Pa)
Rotation speed of the polishing platen: 83 rpm
Rotation speed of head: 77 rpm
Supply of polishing composition: the one-way
Supply amount of polishing composition: 200 mL/min
Polishing time: 5 seconds

### (Rinse Polishing Step)

The obtained polished objects to be polished was installed on another polishing platen in the same polishing device, and a rinse polishing treatment was performed on the surface of the polished objects to be polished using the post-CMP cleaning compositions of Examples 1 to 11 and Comparative Examples 1 and 2 under the following device and conditions.

### <Rinse Polishing Treatment Device and Conditions>

Polishing device: FREX300E, a single-sided polishing device for 300 mm CMP manufactured by Ebara Corporation
Polishing pad: H800 foamed polyurethane pad manufactured by FUJIBO HOLDINGS INC.
Polishing pressure: 2.0 psi
Rotation speed of the polishing platen: 83 rpm
Rotation speed of head: 77 rpm
Supply of post-CMP cleaning composition: the one-way
Supply amount of post-CMP cleaning composition: 300 mL/min
Post-CMP cleaning time: 30 seconds

### <Evaluation>

### (Measurement of Rinse Polishing Amount)

For each of the silicon wafers, a film thickness before and after the rinse polishing treatment was measured using a light interference film thickness measuring device ASET-f5x (manufactured by KLA-Tencor Corporation). Thereafter, a difference in film thickness was calculated from the obtained film thicknesses, and the difference was defined as a rinse polishing amount. The results are shown in Table 1.

(Number of Cerium Residues on Surface of Silicon Wafer with TEOS Film)

First, the TEOS film on the surface of the silicon wafer with a TEOS film, after the rinse polishing treatment, was completely dissolved using a hydrogen fluoride of a concentration of 5%. Thereafter, inductively coupled plasma mass spectrometry (ICP-MS) was performed on the obtained TEOS film solution using an ICP mass spectrometer SPQ9400 (manufactured by SII Nanotechnology Inc.) to measure the number of cerium atoms contained in the solution. Thereafter, the number of cerium atoms contained in the solution was divided by the wafer area to calculate the amount of the cerium residue on the TEOS film per unit area. The results are shown in Table 1.

As shown in Table 1, it was found that the amount of residues containing cerium after the rinse polishing treatment was 10 [10¹⁰ atoms/cm²] or less in all of Examples 1 to 11; and the amount of residues containing cerium after the rinse polishing treatment was more than 10 [10¹⁰ atoms/cm²] in Comparative Examples 1 and 2. From this, it was found that the post-CMP cleaning compositions of Examples 1 to 11 had a higher removal capability of residues containing cerium than the post-CMP cleaning compositions of Comparative Examples 1 and 2.

From the results of Examples 4, 6, 7, and 11 and Comparative Examples 1 and 2, it was found that, when the post-CMP cleaning composition contained the silica and both or one of the nonionic water-soluble polymer and the anionic water-soluble polymer as the water-soluble polymer, the removal capability of residues containing cerium was improved.

The reason for this can be considered as follows. Among the residues, since the particle residue was easily removed by the physical action of the frictional force of the polishing pad, it is considered that the residues containing cerium were efficiently removed by the silica contained in the CMP cleaning composition. It is presumed that the residues removed in this manner were less likely to be reattached to the TEOS film due to the function of the water-soluble polymer contained in the CMP cleaning composition. It is presumed that, since the post-CMP cleaning composition of Comparative Example 1 did not contain the silica, the residues containing cerium were not removed much. On the other hand, in the post-CMP cleaning composition of Comparative Example 2, since the silica was contained, the residues were removed to a certain extent by the physical action, but since the post-CMP cleaning composition did not contain the water-soluble polymer, it is considered that the removed residues were reattached to the surface of the TEOS film.

From the results of Examples 7 and 11, it was found that, when the cation-modified colloidal silica was used as the abrasives contained in the post-CMP cleaning composition, the removal capability of residues containing cerium was improved as compared with the case where the sulfonic acid-modified colloidal silica was used, but the polishing amount of the TEOS film was also very large. Therefore, when the cationic colloidal silica was used as the abrasives, it is considered that it is necessary to adjust the polishing time more carefully in order to set the polishing amount in the rinse polishing treatment to a predetermined value.

In addition, for example, the present invention can adopt the following configuration.

[1] A post-CMP cleaning composition used for cleaning polished objects to be polished as objects to be polished, which has been subjected to a chemical mechanical polishing (CMP) using a polishing composition containing a cerium compound as abrasives, the post-CMP cleaning composition containing:
silica; and
a water-soluble polymer,
in which a concentration of the silica is 0.5% by mass or more and 10% by mass or less.

[2] The post-CMP cleaning composition according to [1], in which the silica has a negative zeta potential.

[3] The post-CMP cleaning composition according to [1] or [2], in which the silica is colloidal silica in which an organic acid is fixed to a surface.

[4] The post-CMP cleaning composition according to [3], in which the colloidal silica is sulfonic acid-modified colloidal silica.

[5] The post-CMP cleaning composition according to any one of [1] to [4], in which the concentration of the silica is 1% by mass or more and 8% by mass or less.

[6] The post-CMP cleaning composition according to any one of [1] to [5], in which the water-soluble polymer is at least one of an anionic water-soluble polymer or a nonionic water-soluble polymer.

[7] The post-CMP cleaning composition according to [6], in which the anionic water-soluble polymer has a sulfo group.

[8] The post-CMP cleaning composition according to [6], in which the nonionic water-soluble polymer has a structural unit derived from a monomer having a vinyl group.

[9] The post-CMP cleaning composition according to any one of [1] to [8], in which a pH is 7 or less.

[10] The post-CMP cleaning composition according to [9], in which the pH is less than 5.

[11] A post-CMP cleaning method for cleaning polished objects to be polished as objects to be polished, which has been subjected to a CMP using a polishing composition containing a cerium compound as abrasives, the post-CMP cleaning method including:
cleaning the polished objects to be polished using the post-CMP cleaning composition according to any one of [1] to [10].

1. A post-CMP cleaning composition used for cleaning polished objects to be polished as objects to be polished, which has been subjected to a chemical mechanical polishing (CMP) using a polishing composition containing a cerium compound as abrasives, the post-CMP cleaning composition containing:
silica; and
a water-soluble polymer,
wherein a concentration of the silica is 0.5% by mass or more and 10% by mass or less.

2. The post-CMP cleaning composition according to claim 1, wherein the silica has a negative zeta potential.

3. The post-CMP cleaning composition according to claim 1, wherein the silica is colloidal silica in which an organic acid is fixed to a surface.

4. The post-CMP cleaning composition according to claim 3, wherein the colloidal silica is sulfonic acid-modified colloidal silica.

5. The post-CMP cleaning composition according to claim 1, wherein the concentration of the silica is 1% by mass or more and 8% by mass or less.

6. The post-CMP cleaning composition according to claim 1, wherein the water-soluble polymer is at least one of an anionic water-soluble polymer or a nonionic water-soluble polymer.

7. The post-CMP cleaning composition according to claim 6, wherein the anionic water-soluble polymer has a sulfo group.

8. The post-CMP cleaning composition according to claim 6, wherein the nonionic water-soluble polymer has a structural unit derived from a monomer having a vinyl group.

9. The post-CMP cleaning composition according to claim 1, wherein a pH is 7 or less.

10. The post-CMP cleaning composition according to claim 9, wherein the pH is less than 5.

11. A post-CMP cleaning method for cleaning polished objects to be polished as objects to be polished, which has been subjected to a CMP using a polishing composition containing a cerium compound as abrasives, the post-CMP cleaning method comprising:
cleaning the polished objects to be polished using the post-CMP cleaning composition according to claim 1.

12. The post-CMP cleaning composition according to claim 2, wherein the silica is colloidal silica in which an organic acid is fixed to a surface.

13. The post-CMP cleaning composition according to claim 12, wherein the colloidal silica is sulfonic acid-modified colloidal silica.

14. The post-CMP cleaning composition according to claim 2, wherein the concentration of the silica is 18 by mass or more and 8% by mass or less.

15. The post-CMP cleaning composition according to claim 2, wherein the water-soluble polymer is at least one of an anionic water-soluble polymer or a nonionic water-soluble polymer.

16. The post-CMP cleaning composition according to claim 15, wherein the anionic water-soluble polymer has a sulfo group.

17. The post-CMP cleaning composition according to claim 15, wherein the nonionic water-soluble polymer has a structural unit derived from a monomer having a vinyl group.

18. The post-CMP cleaning composition according to claim 2, wherein a pH is 7 or less.

19. The post-CMP cleaning composition according to claim 18, wherein the pH is less than 5.

20. A post-CMP cleaning method for cleaning polished objects to be polished as objects to be polished, which has been subjected to a CMP using a polishing composition containing a cerium compound as abrasives, the post-CMP cleaning method comprising:
cleaning the polished objects to be polished using the post-CMP cleaning composition according to claim 2.
